(19) United States
(12) Patent Application Publication
(10) Pub. No.: US 2025/0226223 A1
(43) Pub. Date: Jul. 10, 2025

(54) SUBSTRATE PROCESSING METHOD AND SUBSTRATE PROCESSING SYSTEM

(71) Applicant: Tokyo Electron Limited, Tokyo (JP)

(72) Inventors: Sho KUMAKURA, Miyagi (JP); Kenta ONO, Miyagi (JP); Yuta NAKANE, Miyagi (JP); Tetsuya NISHIZUKA, Miyagi (JP); Masanobu HONDA, Miyagi (JP)

(73) Assignee: Tokyo Electron Limited, Tokyo (JP)

(21) Appl. No.: 19/090,613

(22) Filed: Mar. 26, 2025

Related U.S. Application Data
(63) Continuation of application No. PCT/JP2023/034013, filed on Sep. 20, 2023.

(30) Foreign Application Priority Data
Sep. 27, 2022 (JP) 2022-153628

(51) Int. Cl. H01L 21/033; G03F 7/00; G03F 7/004; G03F 7/09; G03F 7/095; G03F 7/16; H01J 37/32; H01L 21/311

(52) U.S. Cl. CPC H01L 21/0332; G03F 7/0042; G03F 7/094; G03F 7/095; G03F 7/168; G03F 7/70033; H01J 37/32449; H01J 2237/334; H01L 21/31144

(57) ABSTRACT

A substrate processing method includes providing a substrate having an underlayer film and forming a metal-containing resist film on the underlayer film. The forming a metal-containing resist film includes forming a first resist film containing a metal on the underlayer film, and forming a second resist film containing the metal in a composition ratio different from the composition ratio of the metal in the first resist film on the first resist film.

### CROSS-REFERENCE TO RELATED APPLICATIONS

This application is a bypass continuation application of international application No. PCT/JP2023/034013 having an international filing date of Sep. 20, 2023 and designating the United States, the international application being based upon and claiming the benefit of priority from Japanese Patent Application No. 2022-153628, filed on Sep. 27, 2022, the entire contents of each are incorporated herein by reference.

### TECHNICAL FIELD

The present disclosure relates to a substrate processing method and a substrate processing system.

### BACKGROUND

In the related art, there is known a technique in which a thin film that can be patterned using extreme ultraviolet light (hereinafter referred to as “EUV light”) is formed on a semiconductor substrate.

### PRIOR ART DOCUMENT

### Patent Document

Patent Document 1: Japanese patent laid-open publication No. 2021-523403

### SUMMARY

According to one embodiment of the present disclosure, there is provided a substrate processing method including providing a substrate having an underlayer film and forming a metal-containing resist film on the underlayer film. The forming a metal-containing resist film includes forming a first resist film containing a metal on the underlayer film, and forming a second resist film containing the metal in a composition ratio different from the composition ratio of the metal in the first resist film on the first resist film.

### BRIEF DESCRIPTION OF DRAWINGS

The accompanying drawings, which are incorporated in and constitute a part of the specification, illustrate embodiments of the present disclosure, and together with the general description given above and the detailed description of the embodiments given below, serve to explain the principles of the present disclosure.

FIG. 1 is a diagram for explaining a configuration example of a heat treatment system.

FIG. 2 is a diagram for explaining a configuration example of a plasma processing system.

FIG. 3 is a diagram for explaining a configuration example of a capacitively coupled plasma processing apparatus.

FIG. 4 is a diagram for explaining a configuration example of a liquid processing system.

FIG. 5 is a flowchart showing the present processing method.

FIG. 6 is a diagram showing an example of an underlayer film UF of a substrate W.

FIG. 7 is a diagram showing an example of an underlayer film UF of a substrate W.

FIG. 8 is a diagram showing an example of a cross-sectional structure of a substrate W on which a first resist film RM1 is formed.

FIG. 9 is a flowchart showing an example of a process ST21 using an ALD method.

FIG. 10 is a diagram schematically showing an example of a phenomenon occurring on the surface of a substrate W in the process ST21 using the ALD method.

FIG. 11 is a diagram showing an example of a cross-sectional structure of a substrate W on which a second resist film RM2 is formed.

FIG. 12 is a block diagram for explaining a configuration example of a substrate processing system SS.

FIG. 13 is a flowchart showing a method MT.

### DETAILED DESCRIPTION

Reference will now be made in detail to various embodiments, examples of which are illustrated in the accompanying drawings. In the following detailed description, numerous specific details are set forth in order to provide a thorough understanding of the present disclosure. However, it will be apparent to one of ordinary skill in the art that the present disclosure may be practiced without these specific details. In other instances, well-known methods, procedures, systems, and components have not been described in detail so as not to unnecessarily obscure aspects of the various embodiments.

Each embodiment of the present disclosure will be described below.

In one exemplary embodiment, there is provided a substrate processing method, comprising: (a) providing a substrate having an underlayer film; and (b) forming a metal-containing resist film on the underlayer film, wherein (b) includes (b1) forming a first resist film containing a metal on the underlayer film, and (b2) forming a second resist film containing the metal in a composition ratio different from the composition ratio of the metal in the first resist film on the first resist film.

In one exemplary embodiment, the composition ratio of the metal in the second resist film is lower than the composition ratio of the metal in the first resist film.

In one exemplary embodiment, the metal-containing resist film contains at least one metal selected from a group consisting of Sn, Hf, and Ti.

In one exemplary embodiment, in (b), the metal-containing film is formed such that the composition ratio of the metal is changed stepwise or continuously upward from the underlayer film.

In one exemplary embodiment, each of (b1) and (b2) includes applying a solution onto the substrate, and the metal composition ratio of a metal-containing precursor in the solution used in (b2) is lower than the metal composition ratio of the metal-containing precursor in the solution used in (b1).

In one exemplary embodiment, (b1) includes heating the substrate on which the solution is applied.

In one exemplary embodiment, (b2) includes heating the substrate on which the solution is applied.

In one exemplary embodiment, each of (b1) and (b2) includes providing a mixed gas containing a metal-containing gas and an oxidizing gas to the substrate, and the flow rate ratio of the metal-containing gas to the total flow rate of the mixed gas or the total flow rate of the mixed gas is lower in (b2) than in (b1).

In one exemplary embodiment, each of (b1) and (b2) includes alternately supplying a first gas including a metal-containing gas and a second gas including an oxidizing gas, and the flow rate ratio of the first gas to the second gas or the total flow rate of the first gas and the second gas is lower in (b2) than in (b1).

In one exemplary embodiment, the metal-containing gas includes a metal-containing organic precursor.

In one exemplary embodiment, the oxidizing gas includes at least one selected from a group consisting of a H₂O gas, a H₂O₂ gas, an O₃ gas, and an O₂ gas.

In one exemplary embodiment, in (a), the substrate is provided on a substrate support, and the temperature of the substrate support in (b2) is lower than the temperature of the substrate support in (b1).

In one exemplary embodiment, (b1) includes heating the substrate.

In one exemplary embodiment, (b2) includes heating the substrate.

In one exemplary embodiment, (b) includes (b3) forming, on the second resist film, one or more layers of a resist film containing a metal in a composition ratio different from the composition ratios of the metal in the first resist film and the second resist film.

In one exemplary embodiment, the method further comprises: (c) after (b), heating the substrate.

In one exemplary embodiment, the method further comprises: (d) after step (b), exposing the substrate to form an exposed first region and an unexposed second region in the metal-containing resist film.

In one exemplary embodiment, the method further comprises: (e) after step (d), developing the substrate to selectively remove the second region from the metal-containing resist film.

In one exemplary embodiment, there is provided a substrate processing method, comprising: (a) providing a substrate having an underlayer film and a metal-containing resist film formed on the underlayer film, the metal-containing resist film including a first resist film formed on the underlayer film and containing a metal, and a second resist film formed on the first resist film and containing the metal in a composition ratio different from the composition ratio of the metal in the first resist film, the metal-containing resist film including an exposed first region and an unexposed second region; and (b) developing the substrate to selectively remove the second region from the metal-containing resist film.

In one exemplary embodiment, the method further comprises: (f) etching the underlayer film after developing the substrate to selectively remove the second region from the metal-containing resist film.

In one exemplary embodiment, there is provided a substrate processing system, comprising: one or more substrate processing apparatuses; and a controller, wherein the controller is configured to cause the one or more substrate processing apparatuses to execute controls including (a) a control of providing a substrate having an underlayer film, and (b) a control of forming a metal-containing resist film on the underlayer film, and (b) includes (b1) a control of forming a first resist film containing a metal on the underlayer film, and (b2) a control of forming a second resist film containing the metal in a composition ratio different from the composition ratio of the metal in the first resist film on the first resist film.

In one exemplary embodiment, there is provided a substrate processing system, comprising: one or more substrate processing apparatuses; and a controller, wherein the controller is configured to cause the one or more substrate processing apparatuses to execute (a) a control of providing a substrate having an underlayer film and a metal-containing resist film formed on the underlayer film, the metal-containing resist film including a first resist film formed on the underlayer film and containing a metal, and a second resist film formed on the first resist film and containing the metal in a composition ratio different from the composition ratio of the metal in the first resist film, the metal-containing resist film including an exposed first region and an unexposed second region, and (b) a control of developing the substrate to selectively remove the second region from the metal-containing resist film.

Hereinafter, each embodiment of the present disclosure will be described in detail with reference to the drawings. In each drawing, the same or similar elements are designated by the same reference numerals, and duplicated descriptions thereof will be omitted. Unless otherwise specified, the positional relationship such as up, down, left, right, etc. will be described based on the positional relationship shown in the drawings. The dimensional ratio in the drawings does not indicate the actual ratio, and the actual ratio is not limited to the illustrated ratio.

### <Configuration Example of Heat Treatment System>

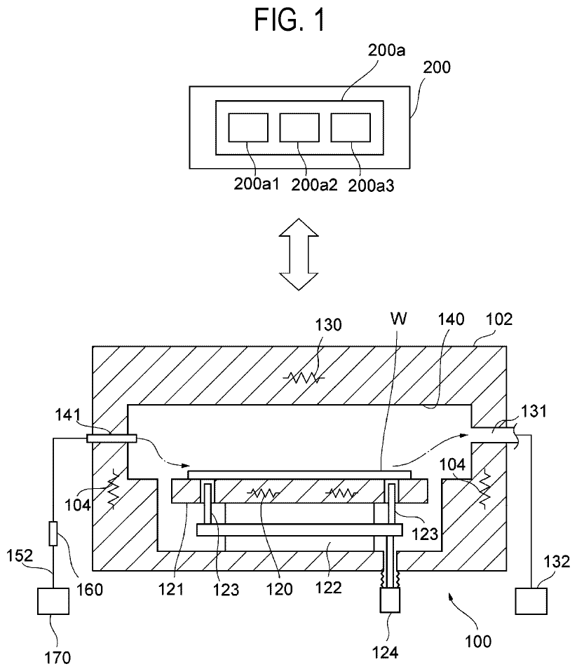

FIG. 1 is a diagram for explaining a configuration example of a heat treatment system. In one embodiment, the heat treatment system includes a heat treatment apparatus 100 and a controller 200. The heat treatment system is an example of a substrate processing system, and the heat treatment apparatus 100 is an example of a substrate processing apparatus.

The heat treatment apparatus 100 includes a processing chamber 102 configured to be able to form a sealed space. The processing chamber 102 is, for example, an airtight cylindrical container, and is configured to be able to adjust the atmosphere therein. A side wall heater 104 is provided on the side wall of the processing chamber 102. A ceiling heater 130 is provided on the ceiling wall (top plate) of the processing chamber 102. A ceiling surface 140 of the ceiling wall (top plate) of the processing chamber 102 is formed as a horizontal flat surface, and the temperature thereof is adjusted by the ceiling heater 130.

A substrate support 121 is provided at the lower side in the processing chamber 102. The substrate support 121 has a substrate support surface on which a substrate W is supported. The substrate support 121 is formed, for example, in a circular shape in a plan view, and the substrate W is held on its horizontally formed surface (upper surface). A stage heater 120 is embedded in the substrate support 121. The stage heater 120 can heat the substrate W held on the substrate support 121. A ring assembly (not shown) may be arranged on the substrate support 121 so as to surround the substrate W. The ring assembly may include one or more annular members. By arranging the ring assembly around the substrate W, the temperature controllability for the outer peripheral region of the substrate W can be improved. The ring assembly may be made of an inorganic material or an organic material depending on the intended heat treatment.

The substrate support 121 is supported in the processing chamber 102 by a pillar 122 provided on the bottom surface of the processing chamber 102. A plurality of lift pins 123 that can be raised and lowered vertically are provided on the circumferential outer side of the pillar 122. The lift pins 123 are respectively inserted into through-holes provided in the substrate support 121. The lift pins 123 are arranged at intervals in the circumferential direction. The raising and lowering operation of the lift pins 123 is controlled by a lifting mechanism 124. When the lift pins 123 protrude from the surface of the substrate support 121, the substrate W can be delivered between a transfer mechanism (not shown) and the substrate support 121.

An exhaust port 131 having an opening is provided on the side wall of the processing chamber 102. The exhaust port 131 is connected to an exhaust mechanism 132 via an exhaust pipe. The exhaust mechanism 132 is composed of a vacuum pump, a valve, etc., and is configured to adjust the exhaust flow rate from the exhaust port 131. The pressure inside the processing chamber 102 is adjusted by adjusting the exhaust flow rate by the exhaust mechanism 132, or the like. A transfer port (not shown) for the substrate W is formed at a position different from the position where the exhaust port 131 is opened on the side wall of the processing chamber 102 so as to be freely opened and closed.

Further, a gas nozzle 141 is provided on the side wall of the processing chamber 102 at a position different from the exhaust port 131 and the transfer port for the substrate W. The gas nozzle 141 supplies a processing gas into the processing chamber 102. The gas nozzle 141 is provided on the side wall of the processing chamber 102 on the opposite side to the exhaust port 131 when viewed from the center of the substrate support 121. That is, the gas nozzle 141 is provided on the side wall of the processing chamber 102 symmetrically to the exhaust port 131 with respect to a vertical imaginary plane passing through the center of the substrate support 121.

The gas nozzle 141 is formed in a rod shape protruding from the side wall of the processing chamber 102 toward the center of the processing chamber 102. The tip of the gas nozzle 141 extends, for example, horizontally from the side wall of the processing chamber 102. The processing gas is discharged into the processing chamber 102 from a discharge port opened at the tip of the gas nozzle 141, flows in the direction indicated by a one-dot chain line arrow in FIG. 1, and is exhausted from the exhaust port 131. The tip of the gas nozzle 141 may have a shape extending obliquely downward toward the substrate W, or may have a shape extending obliquely upward toward the ceiling surface 140 of the processing chamber 102.

The gas nozzle 141 may be provided, for example, in a ceiling wall of the processing chamber 102. The exhaust port 131 may be provided on the bottom surface of the processing chamber 102.

The heat treatment apparatus 100 includes a gas supply pipe 152 connected to the gas nozzle 141 from the outside of the processing chamber 102. A pipe heater 160 for heating the gas in the gas supply pipe 152 is provided around the gas supply pipe 152. The gas supply pipe 152 is connected to a gas supplier 170. The gas supplier 170 includes at least one gas source and at least one flow rate controller. The gas supplier may include a vaporizer that vaporizes a liquid material.

The controller 200 processes computer-executable instructions that cause the heat treatment apparatus 100 to perform various processes described in the present disclosure. The controller 200 may be configured to control each element of the heat treatment apparatus 100 to perform various processes described herein. In one embodiment, a part or all of the controller 200 may be included in the heat treatment apparatus 100. The controller 200 may include a processor 200a1, a memory 200a2, and a communication interface 200a3. The controller 200 is realized by, for example, a computer 200a. The processor 200al may be configured to perform various control operations by reading a program from the memory 200a2 and executing the read program. This program may be stored in the memory 200a2 in advance, or may be acquired via a medium when necessary. The acquired program is stored in the memory 200a2 and is read from the memory 200a2 and executed by the processor 200al. The medium may be various storage media readable by the computer 200a, or may be a communication line connected to the communication interface 200a3. The processor 200al may be a central processing unit (CPU). The memory 200a2 may include a random access memory (RAM), a read only memory (ROM), a hard disk drive (HDD), a solid state drive (SSD), or a combination thereof. The communication interface 200a3 may communicate with the heat treatment apparatus 100 via a communication line such as a local area network (LAN).

### <Configuration Example of Plasma Processing System>

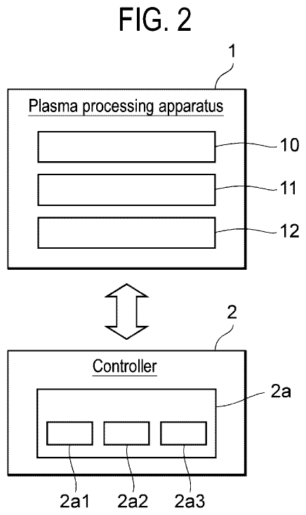

FIG. 2 is a diagram for explaining a configuration example of a plasma processing system. In one embodiment, the plasma processing system includes a plasma processing apparatus 1 and a controller 2. The plasma processing system is an example of a substrate processing system, and the plasma processing apparatus 1 is an example of a substrate processing apparatus. The plasma processing apparatus 1 includes a plasma processing chamber (hereinafter also simply referred to as a “processing chamber”) 10, a substrate support 11, and a plasma generator 12. The plasma processing chamber 10 has a plasma processing space. The plasma processing chamber 10 also has at least one gas supply port for supplying at least one processing gas to the plasma processing space, and at least one gas exhaust port for exhausting the gas from the plasma processing space. The gas supply port is connected to a gas supplier 20 described later, and the gas exhaust port is connected to an exhaust system 40 described later. The substrate support 11 is disposed in the plasma processing space and has a substrate support surface for supporting a substrate.

The plasma generator 12 is configured to generate plasma from the at least one processing gas supplied into the plasma processing space. The plasma formed in the plasma processing space may be capacitively coupled plasma (CCP), inductively coupled plasma (ICP), electron-cyclotron-resonance plasma (ECR plasma), helicon wave plasma (HWP), surface wave plasma (SWP), or the like. Furthermore, it may be possible to use various types of plasma generators including an alternating current (AC) plasma generator and a direct current (DC) plasma generator. In one embodiment, the AC signal (AC power) used in the AC plasma generator has a frequency in the range of 100 kHz to 10 GHz. Thus, the AC signal includes a radio frequency (RF) signal and a microwave signal. In one embodiment, the RF signal has a frequency in the range of 100 kHz to 150 MHz.

The controller 2 processes computer-executable instructions that cause the plasma processing apparatus 1 to perform various processes described in the present disclosure. The controller 2 may be configured to control each element of the plasma processing apparatus 1 to perform various processes described herein. In one embodiment, a part or all of the controller 2 may be included in the plasma processing apparatus 1. The controller 2 is realized by, for example, a computer 2a. The controller 2 may include a processor 2al, a memory 2a2, and a communication interface 2a3. Each component of the controller 2 may be similar to each component of the controller 200 (see FIG. 1) described above.

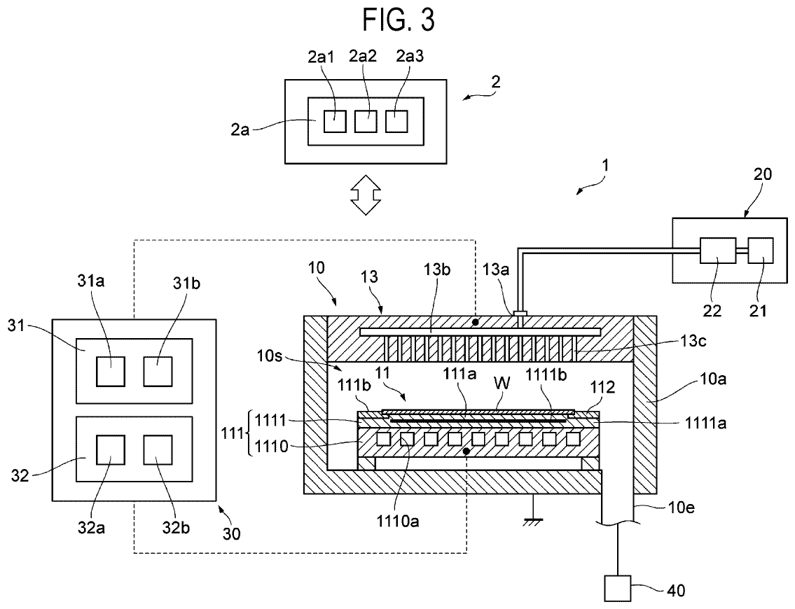

A configuration example of a capacitively coupled plasma processing apparatus will be described below as an example of the plasma processing apparatus 1. FIG. 3 is a diagram for explaining the configuration example of the capacitively coupled plasma processing apparatus.

The capacitively coupled plasma processing apparatus 1 includes a plasma processing chamber 10, a gas supplier 20, a power source 30, and an exhaust system 40. The plasma processing apparatus 1 also includes a substrate support 11 and a gas introducer. The gas introducer is configured to introduce at least one processing gas into the plasma processing chamber 10. The gas introducer includes a shower head 13. The substrate support 11 is arranged in the plasma processing chamber 10. The shower head 13 is disposed above the substrate support 11. In one embodiment, the shower head 13 constitutes at least a part of the ceiling of the plasma processing chamber 10. The plasma processing chamber 10 has a plasma processing space 10s defined by the shower head 13, the side wall 10a of the plasma processing chamber 10, and the substrate support 11. The plasma processing chamber 10 is grounded. The shower head 13 and the substrate support 11 are electrically insulated from the housing of the plasma processing chamber 10.

The substrate support 11 includes a main body 111 and a ring assembly 112. The main body 111 has a central region 111a for supporting the substrate W and an annular region 111b for supporting the ring assembly 112. A wafer is an example of the substrate W. The annular region 111b of the main body 111 surrounds the central region 111a of the main body 111 in a plan view. The substrate W is arranged on the central region 111a of the main body 111, and the ring assembly 112 is arranged on the annular region 111b of the main body 111 so as to surround the substrate W on the central region 111a of the main body 111. Therefore, the central region 111a is also called a substrate support surface for supporting the substrate W, and the annular region 111b is also called a ring support surface for supporting the ring assembly 112.

In one embodiment, the main body 111 includes a base 1110 and an electrostatic chuck 1111. The base 1110 includes a conductive member. The conductive member of the base 1110 may function as a lower electrode. The electrostatic chuck 1111 is arranged on the base 1110. The electrostatic chuck 1111 includes a ceramic member 1111a and an electrostatic electrode 1111b disposed within the ceramic member 1111a. The ceramic member 1111a has a central region 111a. In one embodiment, the ceramic member 1111a also has an annular region 111b. Other members surrounding the electrostatic chuck 1111, such as an annular electrostatic chuck or an annular insulating member, may have the annular region 111b. In this case, the ring assembly 112 may be arranged on the annular electrostatic chuck or the annular insulating member, or may be disposed on both the electrostatic chuck 1111 and the annular insulating member. Furthermore, at least one RF/DC electrode coupled to an RF power source 31 and/or a DC power source 32 described later may be disposed in the ceramic member 1111a. In this case, the at least one RF/DC electrode functions as a lower electrode. When a bias RF signal and/or a DC signal described later is supplied to the at least one RF/DC electrode, the RF/DC electrode is also called a bias electrode. The conductive member of the base 1110 and the at least one RF/DC electrode may function as multiple lower electrodes. In addition, the electrostatic electrode 1111b may function as a lower electrode. Thus, the substrate support 11 includes at least one lower electrode.

The ring assembly 112 includes one or more annular members. In one embodiment, the one or more annular members include one or more edge rings and at least one cover ring. The edge rings are formed of a conductive or insulating material, and the cover ring is formed of an insulating material.

The substrate support 11 may also include a temperature adjustment module configured to adjust the temperature of at least one of the electrostatic chuck 1111, the ring assembly 112, and the substrate to a target temperature. The temperature adjustment module may include a heater, a heat transfer medium, a flow path 1110a, or a combination thereof. A heat transfer fluid such as a brine or a gas flows through the flow path 1110a. In one embodiment, the flow path 1110a is formed in the base 1110, and one or more heaters are arranged in the ceramic member 1111a of the electrostatic chuck 1111. The substrate support 11 may also include a heat transfer gas supplier configured to supply a heat transfer gas to a gap between the back surface of the substrate W and the central region 111a.

The shower head 13 is configured to introduce at least one processing gas from the gas supplier 20 into the plasma processing space 10s. The shower head 13 has at least one gas supply port 13a, at least one gas diffusion chamber 13b, and multiple gas inlets 13c. The processing gas supplied to the gas supply port 13a passes through the gas diffusion chamber 13b and is introduced into the plasma processing space 10s from the multiple gas inlets 13c. The shower head 13 further includes at least one upper electrode. In addition to the shower head 13, the gas introducer may include one or more side gas injectors (SGI) attached to one or more openings formed on the side wall 10a.

The gas supplier 20 may include at least one gas source 21 and at least one flow controller 22. In one embodiment, the gas supplier 20 is configured to supply at least one processing gas from the corresponding gas source 21 through the corresponding flow controller 22 to the shower head 13. Each flow controller 22 may include, for example, a mass flow controller or a pressure-controlled flow controller. Additionally, the gas supplier 20 may include at least one flow modulation device configured to modulate or pulse a flow rate of the at least one processing gas.

The power source 30 includes an RF power source 31 coupled to the plasma processing chamber 10 via at least one impedance matching circuit. The RF power source 31 is configured to supply at least one RF signal (RF power) to at least one lower electrode and/or at least one upper electrode. Thus, plasma is formed from the at least one processing gas supplied to the plasma processing space 10s. Therefore, the RF power source 31 can function as at least a part of the plasma generator 12. In addition, by supplying a bias RF signal to the at least one lower electrode, a bias potential is generated on the substrate W, and ion components in the formed plasma can be drawn into the substrate W.

In one embodiment, the RF power source 31 includes a first RF generation part 31a and a second RF generation part 31b. The first RF generation part 31a is coupled to at least one lower electrode and/or at least one upper electrode via at least one impedance matching circuit and configured to generate a source RF signal (source RF power) for plasma generation. In one embodiment, the source RF signal has a frequency in the range of 10 MHz to 150 MHz. In one embodiment, the first RF generation part 31a may be configured to generate multiple source RF signals having different frequencies. The one or more source RF signals thus generated are supplied to at least one lower electrode and/or at least one upper electrode.

The second RF generation part 31b is coupled to at least one lower electrode via at least one impedance matching circuit and configured to generate a bias RF signal (bias RF power). The frequency of the bias RF signal may be the same as or different from the frequency of the source RF signal. In one embodiment, the bias RF signal has a lower frequency than the frequency of the source RF signal. In one embodiment, the bias RF signal has a frequency in the range of 100 kHz to 60 MHz. In one embodiment, the second RF generation part 31b may be configured to generate multiple bias RF signals having different frequencies. The generated one or more bias RF signals are supplied to at least one lower electrode. In various embodiments, at least one of the source RF signal and the bias RF signal may be pulsed.

The power source 30 may also include a DC power source 32 coupled to the plasma processing chamber 10. The DC power source 32 includes a first DC generation part 32a and a second DC generation part 32b. In one embodiment, the first DC generation part 32a is connected to the at least one lower electrode and configured to generate a first DC signal. The first DC signal thus generated is applied to the at least one lower electrode. In one embodiment, the second DC generation part 32b is connected to the at least one upper electrode and configured to generate a second DC signal. The second DC signal thus generated is applied to the at least one upper electrode.

In various embodiments, the first and second DC signals may be pulsed. In this case, a sequence of voltage pulses is applied to at least one lower electrode and/or at least one upper electrode. The voltage pulses may have a rectangular pulse waveform, a trapezoidal pulse waveform, a triangular pulse waveform, or a combination thereof. In one embodiment, a waveform generation part for generating a sequence of voltage pulses from the DC signal is connected between the first DC generation part 32a and at least one lower electrode. Therefore, the first DC generation part 32a and the waveform generation part constitute a voltage pulse generation part. When the second DC generation part 32b and the waveform generation part constitute a voltage pulse generation part, the voltage pulse generation part is connected to at least one upper electrode. The voltage pulses may have a positive polarity or a negative polarity. Furthermore, the sequence of voltage pulses may include one or more positive polarity voltage pulses and one or more negative polarity voltage pulses in one period. The first and second DC generation parts 32a and 32b may be provided in addition to the RF power source 31, or the first DC generation part 32a may be provided in place of the second RF generation part 31b.

The exhaust system 40 may be connected to, for example, a gas exhaust port 10e provided at the bottom of the plasma processing chamber 10. The exhaust system 40 may include a pressure regulation valve and a vacuum pump. The pressure in the plasma processing space 10s is adjusted by the pressure regulation valve. The vacuum pump may include a turbomolecular pump, a dry pump, or a combination thereof.

### <Configuration Example of Liquid Processing System>

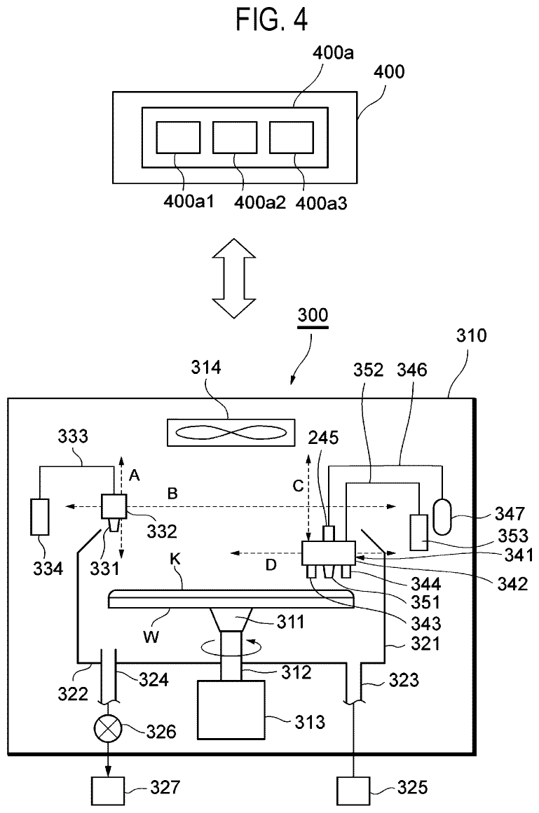

FIG. 4 is a diagram for explaining a configuration example of a liquid processing system. In one embodiment, the liquid processing system includes a liquid processing apparatus 300 and a controller 400. The liquid processing system is an example of a substrate processing system, and the liquid processing apparatus 300 is an example of a substrate processing apparatus.

As shown in FIG. 4, the liquid processing apparatus 300 includes a spin chuck 311 as a substrate support in the processing chamber 310. The spin chuck 311 holds the substrate W horizontally. The spin chuck 311 is connected to a rotary part 312 that can be raised and lowered. The rotary part 312 is connected to a rotational drive part 313 constituted by a motor or the like. By driving the rotational drive part 313, the substrate W held by the spin chuck 311 can be rotated.

A cup 321 is disposed outside the spin chuck 311 to prevent a processing liquid (resist liquid, developing liquid, cleaning liquid, etc.) and a mist of the processing liquid from scattering around the cup 321. A drain pipe 323 and an exhaust pipe 324 are provided at the bottom 322 of the cup 321. The drain pipe 323 is connected to a drainage device 325 such as a drainage pump or the like. The exhaust pipe 324 is connected via a valve 326 to an exhaust device 327 such as an exhaust pump or the like.

An air blower 314 for supplying an air having a required temperature and humidity as a downflow into the cup 321 is provided at the upper part of the processing chamber 310 of the liquid processing apparatus 300.

A processing liquid supply nozzle 331 is used when forming a puddle of processing liquid on the substrate W. This processing liquid supply nozzle 331 is provided on a nozzle support part 332 such as an arm or the like. The nozzle support part 332 can be moved up and down by a drive mechanism as indicated by a reciprocating arrow A shown by a broken line in the figure, and can also be moved horizontally as indicated by a reciprocating arrow B shown by a broken line in the figure. A processing liquid (resist liquid, developing liquid, etc.) is supplied to the processing liquid supply nozzle 331 from a processing liquid supply source 334 via a supply pipe 333.

When a so-called long nozzle with a discharge port having a length equal to or greater than the diameter of the substrate W is used in forming the puddle, a puddle of the processing liquid can be formed on the substrate W by scanning the substrate W from one end to the other end. In the case of a so-called straight type nozzle that discharges a liquid so as to form a liquid column having a width sufficiently smaller than the diameter of the substrate W, the discharge port is positioned above the center of the substrate W, and the processing liquid is discharged while rotating the substrate W, thereby dispersing the processing liquid over the entire surface of the substrate W and forming a puddle of the processing liquid on the substrate W. The puddle of the processing liquid may be formed by causing a straight type nozzle to scan the substrate W in the same manner as the long nozzle, or by arranging a plurality of discharge ports for discharging a liquid over the substrate W just like the straight type nozzle and supplying the processing liquid from each of the discharge ports.

The gas nozzle 341 has a nozzle body 342. The nozzle body 342 is provided on a nozzle support part such as an arm or the like. The nozzle support part can be freely raised and lowered by a drive mechanism as indicated by a reciprocating arrow C shown by a broken line in the figure, and can also be freely moved horizontally as indicated by a reciprocating arrow D shown by a broken line.

The gas nozzle 341 has two nozzle discharge ports 343 and 344. The nozzle discharge ports 343 and 344 are formed by branching off from a gas flow path 345. The gas flow path 345 is connected to a gas supply source 347 via a gas supply pipe 346. In the gas supply source 347, an inert gas or a non-oxidizing gas, such as a nitrogen gas or the like, is prepared. For example, when a nitrogen gas is supplied from the gas flow path 345 to the gas nozzle 341, the nitrogen gas is discharged from each of the nozzle discharge ports 343 and 344.

Further, the gas nozzle 341 is provided with a cleaning liquid supply nozzle 351 for removing the processing liquid from the substrate W after the liquid processing. The cleaning liquid supply nozzle 351 is connected to a cleaning liquid supply source 353 via a cleaning liquid supply pipe 352. For example, pure water is used as a cleaning liquid. The cleaning liquid supply nozzle 351 is positioned between the two nozzle discharge ports 343 and 344. However, the position of the cleaning liquid supply nozzle 351 is not limited thereto. The cleaning liquid supply nozzle 351 may be configured independently of the gas nozzle 341.

The controller 400 processes computer-executable instructions that cause the liquid processing apparatus 300 to perform various processes described in the present disclosure. The controller 400 may be configured to control each element of the liquid processing apparatus 300 to perform various processes described herein. In one embodiment, a part or all of the controller 400 may be included in the liquid processing apparatus 300. The controller 400 is realized, for example, by a computer 400a. The computer 400a may include a processor 400al, a memory 400a2, and a communication interface 400a3. Each component of the controller 400 may be similar to each component of the controller 200 (see FIG. 1) described above.

### <Example of Substrate Processing Method>

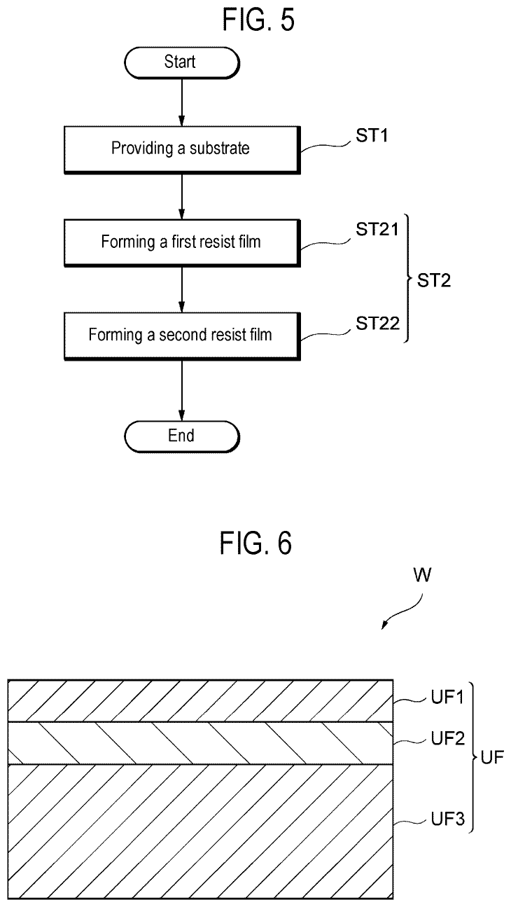

FIG. 5 is a flowchart showing a substrate processing method (hereinafter also referred to as “the present processing method”) according to an exemplary embodiment. The present processing method includes step ST1 of providing a substrate having an underlayer film, and step ST2 of forming a metal-containing resist film on the underlayer film. In one embodiment, the formation process of the metal-containing resist film (hereinafter also referred to as “film formation process”) in step ST2 is performed by a dry process (hereinafter also referred to as “dry film formation”) using a processing gas. In one embodiment, the film formation process in step ST2 is performed by a wet process (hereinafter also referred to as “wet film formation”) using a solution. In one embodiment, the film formation process in step ST2 is performed using both wet film formation and dry film formation.

The present processing method may be performed using any one of the above-mentioned substrate processing systems (see FIGS. 1 to 4), or may be performed using two or more of these substrate processing systems. For example, the present processing method may be performed in the heat treatment system (see FIG. 1). In the following, an example will be described in which the controller 200 controls each part of the heat treatment apparatus 100 to perform the present processing method on the substrate W.

### (Step ST1: Providing Substrate)

First, in step ST1, the substrate W is provided in the processing chamber 102 of the heat treatment apparatus 100. The substrate W is provided on the substrate support 121 via the lift pins 123. After the substrate W is placed on the substrate support 121, the temperature of the substrate support 121 is adjusted to a set temperature. The set temperature may be, for example, 300 degrees C. or less, and may be 100 degrees C. or more and 300 degrees C. or less. The temperature adjustment of the substrate support 121 may be performed by controlling the output of one or more heaters among the side wall heater 104, the stage heater 120, the ceiling heater 130, and the pipe heater 160 (hereinafter collectively referred to as “each heater”). In the present processing method, the temperature of the substrate support 121 may be adjusted to a set temperature before step ST1. That is, after the temperature of the substrate support 121 is adjusted to the set temperature, the substrate W may be provided on the substrate support 121.

The substrate W may be used in the manufacture of a semiconductor device. The semiconductor device may include, for example, a memory device such as a DRAM or a 3D-NAND flash memory, and a logic device. The substrate W has an underlayer film UF. The underlayer film UF may be an organic film, a dielectric film, a metal film, a semiconductor film, or a stacked film thereof formed on a silicon wafer. In one embodiment, the underlayer film UF includes, for example, at least one selected from a group consisting of a silicon-containing film, a carbon-containing film, and a metal-containing film.

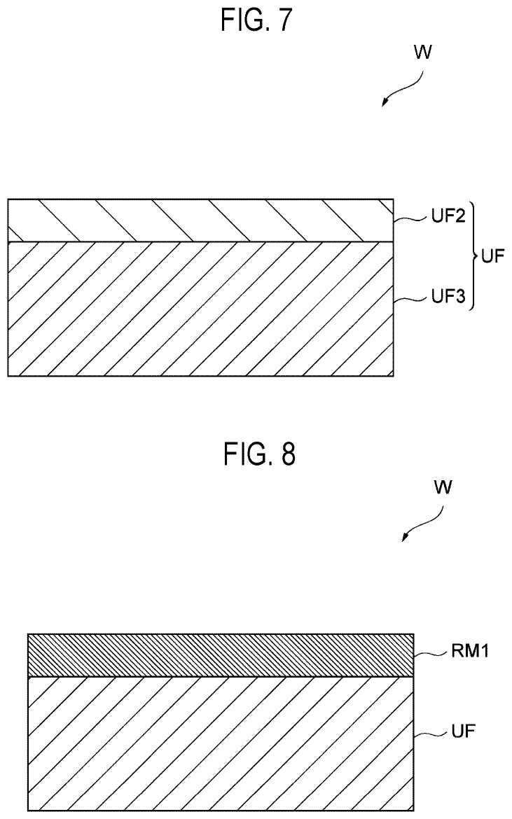

FIGS. 6 and 7 are diagrams showing an example of an underlayer film UF of a substrate W. As shown in FIG. 6, the underlayer film UF may be composed of a first film UF1, a second film UF2, and a third film UF3. As shown in FIG. 7, the underlayer film UF may be composed of a second film UF2 and a third film UF3. In one embodiment, a water-repellent treatment may be applied to the surface of the underlayer film UF to enhance adhesion with the metal-containing film.

The first film UF1 is, for example, a spin-on-glass (SOG) film, a SiC film, a SiON film, a Si-containing anti-reflective film (SiARC), or an organic film. The second film UF2 is, for example, a spin-on-carbon (SOC) film, an amorphous carbon film, or a silicon-containing film. The third film UF3 is, for example, a silicon-containing film. The silicon-containing film is, for example, a silicon oxide film, a silicon nitride film, a silicon oxynitride film, a silicon carbonitride film, a polycrystalline silicon film, or a carbon-containing silicon film. The third film UF3 may be composed of a plurality of types of stacked silicon-containing films. For example, the third film UF3 may be composed of a silicon oxide film and a silicon nitride film that are alternately stacked one above another. The third film UF3 may also be composed of a silicon oxide film and a polycrystalline silicon film that are stacked one above another. The third film UF3 may also be a stacked film that includes a silicon nitride film, a silicon oxide film, and a polycrystalline silicon film. The third film UF3 may also be composed of a silicon oxide film and a silicon carbonitride film that are stacked one above another. The third film UF3 may also be a stacked film that includes a silicon oxide film, a silicon nitride film, and a silicon carbonitride film.

A part or all of the underlayer film UF may be formed inside the processing chamber 102 of the heat treatment apparatus 100, or may be formed using other systems, such as a plasma processing system (see FIGS. 2 and 3) or a liquid processing system (see FIG. 4).

### (Step ST2: Formation of Metal-Containing Resist Film)

Next, in step ST2, a metal-containing resist film RM is formed on the underlayer film UF of the substrate W. In one embodiment, step ST2 includes step ST21 of forming a first resist film RM1 and step ST22 of forming a second resist film RM2.

### (Step ST21: Formation of First Resist Film)

In step ST21, the first resist film RM1 is formed. FIG. 8 is a diagram showing an example of the cross-sectional structure of the substrate W on which the first resist film RM1 is formed in step ST21. As shown in FIG. 8, the first resist film RM1 is formed on the surface of the underlayer film UF. The first resist film RM1 is a film containing a metal. In one embodiment, the first resist film RM1 contains at least one metal selected from a group consisting of Sn, Hf, and Ti. In one example, the first resist film RM1 may contain Sn.

The formation of the first resist film RM1 in step ST21 may be performed using various methods such as an atomic layer deposition method (hereinafter referred to as an “ALD method”), a chemical vapor deposition method (hereinafter referred to as a “CVD method”), etc. Hereinafter, an example of various methods for forming the first resist film RM1 will be described.

### [ALD Method]

In one embodiment, the ALD method forms the first resist film RM1 by causing a specific material to adsorb onto and react with the underlayer film UF of the substrate W in a self-regulating manner.

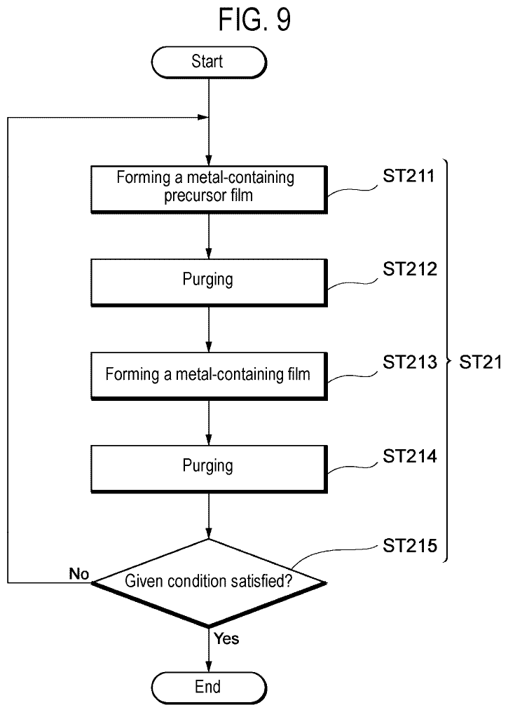

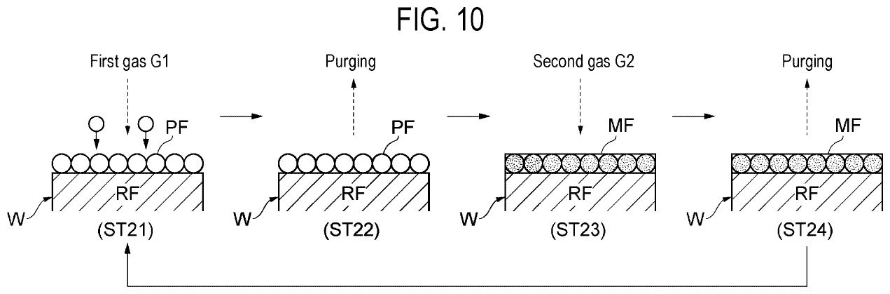

FIG. 9 is a flowchart showing an example of step ST21 using an ALD method. As shown in FIG. 9, step ST21 using the ALD method includes step ST211 of forming a metal-containing precursor film, first purge step ST212, step ST213 of forming a metal-containing film from the metal-containing precursor film, second purge step ST214, and determination step ST215. The first purge step ST212 and the second purge step ST214 may or may not be performed. FIG. 10 is a diagram schematically showing an example of a phenomenon occurring on the surface of the substrate W in the step ST21 using the ALD method.

In step ST211, as shown in FIG. 10, a first gas G1 containing a metal-containing precursor is supplied to the surface of the underlayer film UF to form a metal-containing precursor film PF. In one embodiment, the metal-containing precursor is a metal-containing organic precursor. In one embodiment, the metal-containing precursor contains at least one metal selected from a group consisting of Sn, Hf, and Ti. For example, the metal-containing precursor contains at least one compound selected from a group consisting of a stannane compound, an oxygen-containing tin compound, a nitrogen-containing tin compound, and a halogenated tin compound. Examples of the stannane compound may include stannane, tetramethylstannane, tributylstannane, phenyltrimethylstannane, tetravinylstannane, dimethyldichlorostannane, butyltrichlorostannane, trichlorophenylstannane, and the like. Examples of the oxygen-containing tin compound may include tributyltin methoxide, tert-butoxide tin, dibutyltin diacetate, triphenyltin acetate, tributyltin oxide, triphenyltin acetate, triphenyltin hydroxide, butylchlorotin dihydroxide, acetylacetonate tin, and the like. Examples of the nitrogen-containing tin compound may include dimethylaminotrimethyltin, tris (dimethylamino) tert-butyltin, azidotrimethyltin, tetrakis(dimethylamino) tin, N,N′-di-tert-butyl-2,3-diamidinobutane tin (II), and the like. Examples of the halide tin compound may include tin chloride, tin bromide, tin iodide, dimethyltin dichloride, butyltin trichloride, phenyltin trichloride, and the like.

In one embodiment, in step ST211, a first gas G1 is supplied into the processing chamber 102 through the gas nozzle 141. Then, in the processing chamber 102, a metal-containing precursor of the first gas G1 is adsorbed onto the surface of the underlayer film UF to form a metal-containing precursor film PF. The metal-containing precursor film PF may contain, for example, Sn, Hf, Ti, etc. The metal-containing precursor film PF may be a metal complex. The metal complex may contain, for example, amino tin.

In step ST212, the gas in the processing chamber 102 is exhausted from the exhaust port 131 by the exhaust mechanism 132. At this time, an inert gas or the like may be supplied to the substrate W. Thus, an excess gas such as a metal-containing precursor is purged. The inert gas is, for example, a rare gas such as He, Ar, Ne, Kr or Xe, or a nitrogen gas.

In step ST213, as shown in FIG. 10, a second gas G2 containing an oxidizing gas is supplied to the surface of the substrate W. The second gas G2 reacts with the metal-containing precursor film PF to form a metal-containing film from the metal-containing precursor film PF. The oxidizing gas contained in the second gas G2 is a gas that reacts with the metal-containing precursor adsorbed onto the surface of the underlayer film UF. The oxidizing gas may be at least one selected from a group consisting of a H₂O gas, a H₂O₂ gas, an O₃ gas, and an O₂ gas. In one embodiment, in step ST213, the second gas G2 is supplied into the processing chamber 102 through the gas nozzle 141. Then, the second gas G2 reacts with the metal-containing precursor film PF in the processing chamber 102 to form a metal-containing film.

In step ST214, the gas in the processing chamber 102 is exhausted from the exhaust port 131 by the exhaust mechanism 132. At this time, an inert gas or the like may be supplied to the substrate W. As a result, an excess gas such as the second gas G2 is purged.

In step ST215, it is determined whether a given condition for ending step ST21 is satisfied. The given condition may be that a cycle including steps ST211 to ST214 has been performed a preset number of times. The number of times may be once, less than five times, five or more times, or ten or more times. If it is determined in step ST215 that the given condition is not satisfied, the process returns to step ST211. If it is determined in step ST215 that the given condition is satisfied, the process ST21 is ended. For example, the given condition may be a condition regarding the dimensions of the metal-containing film after step ST214. That is, after step ST214, it may be determined whether the dimension of the metal-containing film (the thickness of the resist film) has reached a given value or range, and the cycle including steps ST211 to ST214 may be repeated until the given value or range is reached. The dimension of the first resist film RM1 may be measured by an optical measurement device. In this manner, the first resist film RM1 is formed on the underlayer film UF.

### [CVD Method]

In one embodiment, in the CVD method, the first resist film RM1 is formed by a mixed gas GM containing a metal-containing gas and an oxidizing gas. The metal-containing gas may contain a metal-containing precursor as described in the ALD method. The oxidizing gas may be at least one selected from a group consisting of a H₂O gas, a H₂O₂ gas, an O₃ gas, and an O₂ gas. In one embodiment, the mixed gas GM is supplied into the processing chamber 102 through the gas nozzle 141. The mixed gas GM chemically reacts on the substrate W, thereby forming the first resist film RM1 on the underlayer film UF.

In step ST21, the temperature of the substrate support 121 may be controlled to a first temperature. The temperature of the substrate support 121 may be adjusted by controlling the output of one or more of the heaters. The first temperature may be, for example, 0 degrees C. or more and 250 degrees C. or less, or 0 degrees C. or more and 150 degrees C. or less, and is 150 degrees C. in one example.

In one embodiment, step ST21 may include heating and baking the first resist film RM1. The baking may be performed in an air atmosphere or an inert atmosphere. The baking may be performed by heating the substrate W to 50 degrees C. or more and 250 degrees C. or less, 50 degrees C. or more and 200 degrees C. or less, or 80 degrees C. or more and 150 degrees C. or less. In one embodiment, each heater of the heat treatment apparatus 100 may function as a heating part that performs baking. In one embodiment, the baking may be performed using a heat treatment system other than the heat treatment apparatus 100.

### (Step ST22: Formation of Second Resist Film)

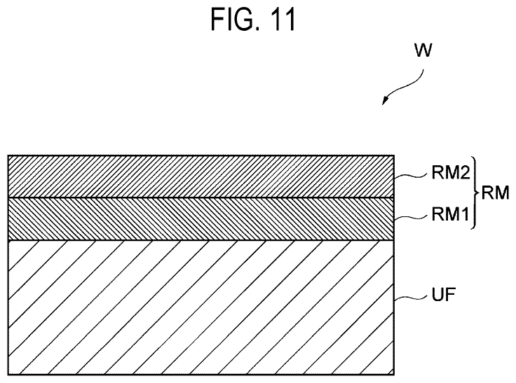

In step ST22, the second resist film RM2 is formed. FIG. 11 is a diagram showing an example of the cross-sectional structure of the substrate W on which the second resist film RM2 is formed in step ST22. As shown in FIG. 11, the second resist film RM2 is formed on the first resist film RM1. The second resist film RM2 is a film containing a metal. In one embodiment, the second resist film RM2 contains at least one metal selected from a group consisting of Sn, Hf, and Ti. In one example, the second resist film RM2 may contain Sn.

In one embodiment, the type of metal contained in the second resist film RM2 is the same as that of the first resist film RM1. In one example, both the first resist film RM1 and the second resist film RM2 may contain Sn. In one embodiment, the type of metal contained in the second resist film RM2 may be different from that of the first resist film RM1. In one example, the first resist film RM1 may contain at least one metal selected from a group consisting of Sn, Hf, and Ti, and the second resist film RM2 may contain at least one metal selected from a group consisting of Sn, Hf, and Ti that is different from the metal of the first resist film RM1.

The composition ratio of the metal in the second resist film RM2, i.e., the ratio of the metal element in the entire second resist film RM2 (atomic percent: at %), is different from the composition ratio of the metal in the first resist film RM1. That is, the metal-containing resist film RM is changed in the composition ratio of the metal from the underlayer film UF toward the upper side in the thickness direction. In one embodiment, the composition ratio of the metal in the second resist film RM2 is lower than the composition ratio of the metal in the first resist film RM1. That is, the metal-containing resist film RM may have a composition ratio of the metal that decreases from the underlayer film UF toward the upper side in the thickness direction. In one embodiment, the film density of the metal in the second resist film RM2 is lower than the film density of the metal in the first resist film RM1. That is, the metal-containing resist film RM may have a film density of the metal that decreases from the underlayer film UF toward the upper side in the thickness direction.

The formation of the second resist film RM2 in step ST22 may be performed using various methods such as an ALD method or a CVD method. In one embodiment, the formation of the second resist film RM2 in step ST22 is performed using the same type of method as the formation of the first resist film RM1 in step ST21. For example, the ALD method may be used in steps ST21 and ST22. For example, the CVD method may be used in steps ST21 and ST22.

When the ALD method is used, in step ST22, a first gas G1 containing a metal-containing precursor and a second gas G2 containing an oxidizing gas are supplied to the substrate W as described in step ST21 using FIG. 9.

In one embodiment, the flow rate ratio of the first gas G1 to the second gas G2 in step ST22 is different from the flow rate ratio in step ST21. In one embodiment, the flow rate ratio of the first gas G1 to the second gas G2 in step ST22 is lower than the flow rate ratio in step ST21. In this case, the composition ratio of the metal in the second resist film RM2 may be lower than the composition ratio of the metal in the first resist film RM1.

In one embodiment, the total flow rate of the first gas G1 and the second gas G2 in step ST22 is different from the total flow rate in step ST21. In one embodiment, the total flow rate of the first gas G1 and the second gas G2 in step ST22 is smaller than the total flow rate in step ST21. In this case, the composition ratio of the metal in the second resist film RM2 may be lower than the composition ratio of the metal in the first resist film RM1.

When the CVD method is used, in step ST22, a mixed gas GM containing a metal-containing gas and an oxidizing gas is supplied to the substrate W in the same manner as described in step ST21.

In one embodiment, the flow rate ratio of the metal-containing gas to the total flow rate of the mixed gas GM in step ST22 is different from the flow rate ratio in step ST21. In one embodiment, the flow rate ratio of the metal-containing gas to the total flow rate of the mixed gas GM in step ST22 is smaller than the flow rate ratio in step ST21. In this case, the composition ratio of the metal in the second resist film RM2 may be lower than the composition ratio of the metal in the first resist film RM1.

In one embodiment, the total flow rate of the mixed gas GM in step ST22 is different from the total flow rate of the mixed gas GM in step ST21. In one embodiment, the total flow rate of the mixed gas GM in step ST22 is smaller than the total flow rate of the mixed gas GM in step ST21. In this case, the composition ratio of the metal in the second resist film RM2 may be lower than the composition ratio of the metal in the first resist film RM1.

In step ST22, the temperature of the substrate support 121 may be controlled to a first temperature which is the same as that in step ST21, or may be controlled to a second temperature which is different from the first temperature. The temperature of the substrate support 121 may be adjusted by controlling the output of one or more of the heaters. In one embodiment, the second temperature is lower than the first temperature. In this case, the composition ratio of the metal in the second resist film RM2 may be lower than the composition ratio of the metal in the first resist film RM1. The second temperature may be, for example, 0 degrees C. or more and 250 degrees C. or less, 0 degrees C. or more and 150 degrees C. or less, and is 150 degrees C. in one example.

In one embodiment, step ST22 may include heating and baking the second resist film RM2. The baking may be performed in an air atmosphere or an inert atmosphere. The baking may be performed by heating the substrate W to 50 degrees C. or more and 250 degrees C. or less, 50 degrees C. or more and 200 degrees C. or less, or 80 degrees C. or more and 150 degrees C. or less. In one embodiment, each heater of the heat treatment apparatus 100 may function as a heating part that performs baking. In one embodiment, the baking may be performed using a heat treatment system other than the heat treatment apparatus 100.

In the present processing method, the first resist film RM1 containing a metal is formed on the underlayer film UF in step ST21, and then the second resist film RM2 containing the metal in a composition ratio different from that of the first resist film RM1 is formed on the first resist film RM1 in step ST22. That is, the metal-containing resist film RM has a metal composition ratio that is changed along the thickness direction from the underlayer film UF. By changing the metal composition ratio, it is possible to change the photosensitivity of the metal-containing resist film RM along the thickness direction. As a result, according to the present processing method, it is possible to adjust the exposure sensitivity of the resist film.

The metal-containing resist film RM may be exposed to EUV in subsequent steps. In the EUV exposure, the amount of exposure may decrease in the thickness direction of the metal-containing resist film RM (toward the side closer to the underlayer film UF) due to stochastic fluctuations in the photon distribution and shallow depth of focus. In this regard, for example, the composition ratio of metal in the first resist film RM1 may be made higher than the composition ratio of metal in the second resist film RM2, and the photosensitivity of the first resist film RM1 may be made higher than the photosensitivity of the second resist film RM2. As a result, it is possible to compensate for the decrease in the amount of exposure in the thickness direction of the metal-containing resist film RM during the EUV exposure, and to suppress the variation in the exposure reaction (hardening) in the thickness direction of the metal-containing resist film RM (consequently, the variation in the development resistance).

In one embodiment, the metal-containing resist film RM may be composed of three or more layers of a film containing a metal. For example, the present processing method may further include forming a third resist film RM3 containing a metal on the second resist film RM2 after the end of step ST22. In this case, the composition ratio of the metal in the third resist film RM3 may be different from that of the first resist film RM1 and the second resist film RM2. In one embodiment, the composition ratio of the metal in the third resist film RM3 is lower than that of the second resist film RM2, and the composition ratio of the metal in the second resist film RM2 is lower than that of the first resist film RM1. That is, the metal-containing resist film RM may have a composition ratio of the metal that decreases stepwise (in this case, in three steps) from the underlayer film UF toward the upper side in the thickness direction. The same applies when the metal-containing resist film RM is composed of four or more layers of a film.

In one embodiment, during step ST21, the configurations (type, flow rate, and flow rate ratio) of the processing gases (the first gas G1, the second gas G2, and the mixed gas GM) and the film formation conditions such as the temperature of the substrate support 11 may be changed. This makes it possible to continuously change the composition ratio of metal in the thickness direction of the first resist film RM1. In one embodiment, during step ST22, the configurations (type, flow rate, and flow rate ratio) of the processing gases (the first gas G1, the second gas G2, and the mixed gas GM) and the film formation conditions such as the temperature of the substrate support 11 may be changed. This makes it possible to continuously change the composition ratio of metal in the thickness direction of the second resist film RM2.

In one embodiment, the present processing method may be performed by a dry process using a plasma processing system (see FIGS. 2 and 3). For example, the substrate W may be provided on the substrate support 11 in the processing chamber 10 of the plasma processing apparatus 1 (step ST1), and the processing gases may be supplied from the gas supplier 20 into the processing chamber 10 to form a metal-containing resist film RM (step ST2).

When using the plasma processing system, the above-mentioned ALD method or CVD method may be used in step ST21 and step ST22. The configurations (type, flow rate, and flow rate ratio) of the processing gases (the first gas G1, the second gas G2, the mixed gas GM, etc.), the temperature of the substrate support 11, and the like in step ST21 and step ST22 may be changed in the same manner as when using the heat treatment system. The temperature of the substrate support 11 may be adjusted by controlling the pressure of the heat transfer gas (e.g., He) between the temperature control module or the electrostatic chuck 1111 and the back surface of the substrate W. In step ST21 and step ST22, plasma may be generated from the processing gas, or plasma may not be generated. As in the case of using the heat treatment system (see FIG. 1), step ST21 and/or step ST22 may include heating the substrate W to perform a baking process. The baking process may be performed, for example, using the heat treatment system.

In one embodiment, the present processing method may be performed by a wet process using the liquid processing system (see FIG. 4). That is, the substrate W may be provided on the spin chuck 311 in the processing chamber 310 of the liquid processing apparatus 300 (step ST1), and a film-forming solution (resist liquid) may be applied onto the substrate W from the processing liquid supply nozzle 331 to form a metal-containing resist film RM (step ST2).

When using the liquid processing system, in steps ST21 and ST22, the film-forming solution (resist liquid) may contain a metal-containing precursor. In one embodiment, the metal-containing precursor is a metal-containing organic precursor. In one embodiment, the metal-containing precursor contains at least one metal selected from a group consisting of Sn, Hf, and Ti. For example, the metal-containing precursor contains at least one compound selected from a group consisting of a stannane compound, an oxygen-containing tin compound, a nitrogen-containing tin compound, and a halogenated tin compound. Examples of the stannane compound may include stannane, tetramethylstannane, tributylstannane, phenyltrimethylstannane, tetravinylstannane, dimethyldichlorostannane, butyltrichlorostannane, trichlorophenylstannane, and the like. Examples of the oxygen-containing tin compound may include tributyltin methoxide, tert-butoxide tin, dibutyltin diacetate, triphenyltin acetate, tributyltin oxide, triphenyltin acetate, triphenyltin hydroxide, butylchlorotin dihydroxide, acetylacetonate tin, and the like. Examples of the nitrogen-containing tin compound may include dimethylaminotrimethyltin, tris (dimethylamino) tert-butyltin, azidotrimethyltin, tetrakis(dimethylamino) tin, N,N′-di-tert-butyl-2,3-diamidinobutane tin (II), and the like. Examples of the halide tin compound may include tin chloride, tin bromide, tin iodide, dimethyltin dichloride, butyltin trichloride, phenyltin trichloride, and the like.

When the liquid processing system is used, in one embodiment, the metal composition ratio of the metal-containing precursor contained in the film-forming solution (resist liquid) in step ST22 is different from the composition ratio in step ST21. In one embodiment, the composition ratio of the metal-containing precursor contained in the film-forming solution (resist liquid) in step ST22 is lower than the composition ratio in step ST21. In this case, the metal composition ratio in the second resist film RM2 may be lower than the composition ratio in the first resist film RM1.

When the liquid processing system is used, step ST21 and/or step ST22 may include heating and baking the substrate W after the solution is applied onto the substrate W. In one embodiment, the baking may be performed, for example, by using the heat treatment system (see FIG. 1). The baking may be performed in an air atmosphere or an inert atmosphere. The baking may be performed by heating the substrate W to 50 degrees C. or more and 250 degrees C. or less, 50 degrees C. or more and 200 degrees C. or less, or 80 degrees C. or more and 150 degrees C. or less.

In one embodiment, the deposition of the metal-containing resist film RM (step ST2) in the present processing method may be performed by both a dry process using the heat treatment system (see FIG. 1) or the plasma processing system (see FIGS. 2 and 3) and a wet process using the liquid processing system (see FIG. 4). For example, the first resist film RM1 may be wet-deposited in step ST21, and the second resist film RM2 may be dry-deposited in step ST22. In addition, for example, the first resist film RM1 may be dry-deposited in step ST21, and the second resist film RM2 may be wet-deposited in step ST22.

In one embodiment, the present processing method may include the following steps ST3 to ST5 after step ST2.

### (Step ST3: EUV Exposure)

After step ST2, the substrate W is transferred to an exposure apparatus, and the metal-containing resist film RM is irradiated with EUV through an exposure mask (reticle). This forms a substrate W that includes an underlayer film UF and a metal-containing resist film RM having an exposed first region and an unexposed second region. The first region is a region corresponding to an opening provided in the exposure mask (reticle). The second region is a region corresponding to a pattern provided in the exposure mask (reticle). EUV has a wavelength in the range of, for example, 10 to 20 nm. EUV may have a wavelength in the range of 11 to 14 nm, and in one example, has a wavelength of 13.5 nm. The exposed substrate is transferred from the exposure apparatus to the heat treatment apparatus under atmosphere control, and is subjected to a heat treatment, i.e., a post-exposure bake (PEB). An additional heat treatment may be performed on the substrate W after PEB.

### (Step ST4: Development)

Next, in step ST4, the metal-containing resist film RM of the substrate W is developed, and the second region is selectively removed. As described above, the metal-containing resist RM of the present processing method has its exposure sensitivity adjusted by changing the composition of metal along the thickness direction from the underlayer film UF. Therefore, when the metal-containing resist RM is developed in step ST4, it is possible to suppress the variation in development. The development of the metal-containing resist film RM may be performed by dry development, wet development, or a combination of dry development and wet development.

When dry-developing the metal-containing resist film RM, at least one developing gas is supplied into the processing chamber 102 via the gas nozzle 141. In one embodiment, the developing gas may include at least one selected from a group consisting of hydrogen bromide (HBr), hydrogen fluoride (HF), hydrogen chloride (HCl), boron trichloride (BCl₃), organic acid (e.g., carboxylic acid or alcohol), and a β-dicarbonyl compound. The carboxylic acid in the developing gas may include at least one selected from a group consisting of formic acid (HCOOH), acetic acid (CH₃COOH), trichloroacetic acid (CCl₃COOH), monofluoroacetic acid (CFH₂COOH), difluoroacetic acid (CF₂FCOOH), trifluoroacetic acid (CF₃COOH), chloro-difluoroacetic acid (CClF₂COOH), sulfur-containing acetic acid, thioacetic acid (CH₃COSH), thioglycolic acid (HSCH₂COOH), trifluoroacetic anhydride ((CF₃CO)₂O), and acetic anhydride ((CH₃CO)₂O). The alcohol in the developing gas may include nonafluoro-tert-butyl alcohol ((CF₃)₃COH). The β-dicarbonyl compound in the developing gas may be, for example, acetylacetone (CH₃C(O)CH₂C(O)CH₃), trichloroacetylacetone (CCl₃C(O)CH₂C(O)CH₃), hexachloroacetylacetone (CCl₃C(O)CH₂C(O)CCl₃), trifluoroacetylacetone (CF₃C(O)CH₂C(O)CH₃), or hexafluoroacetylacetone (HFAc, CF₃C(O)CH₂C(O)CF₃). In step ST4, development may be performed by a thermal reaction between the developing gas and the region RD, or development may be performed by a chemical reaction between the region RD and chemical species in the plasma generated from the developing gas.

The metal-containing resist film RM includes a plurality of resist films RM (e.g., a first resist film RM1 and a second resist film RM2) having different compositions. Therefore, in step ST4, the boundary region between the first resist film RM1 and the second resist film RM2 may be scraped in the horizontal direction, consequently forming a depression or the like. Thus, in step ST4, the metal-containing resist may be developed while protecting the side wall of the metal-containing resist RM. For example, when the metal-containing resist film RM1 is dry-developed, a gas having a side wall protection effect (hereinafter also referred to as a “protective gas”) may be added to the above-mentioned developing gas. By adding the protective gas, a passivation layer is formed on the side wall of the metal-containing resist film RM, which makes it possible to suppress the scraping of the metal-containing resist film RM in the horizontal direction.

The protective gas may be an oxygen-containing gas. In one example, the protective gas may be at least one selected from a group consisting of O₂, CO₂, CO, COS, SO₂, and H₂O. When an oxygen-containing gas is added as the protective gas, a layer containing Sn—O bonds is formed on the side wall of the metal-containing resist film RM, which can suppress the horizontal scraping of the metal-containing resist film RM.

In addition, a gas containing carbon and/or silicon may be used as the protective gas. For example, at least one selected from a group consisting of hydrocarbon, fluorocarbon, and hydrofluorocarbon may be used as the carbon-containing gas. For example, SiCl₄ may be used as the silicon-containing gas. In addition, amino tin or the like may be used as the protective gas. With these protective gases, a protective layer is formed on the side wall of the metal-containing resist film RM, which can suppress the horizontal scraping of the metal-containing resist film RM.

In one embodiment, step ST4 may include heating and baking the developed metal-containing resist film RM. The baking may be performed in an air atmosphere or an inert atmosphere. The baking may be performed by heating the substrate W to 150 degrees C. or more and 250 degrees C. or less. In one embodiment, each heater of the heat treatment apparatus 100 may function as a heating part that performs baking. In one embodiment, the baking may be performed using a heat treatment system other than the heat treatment apparatus 100.

### (Step ST5: Etching)

After step ST4, the underlayer film UF may be etched. The etching may be performed, for example, by generating plasma from the processing gas in the processing chamber 10 of the plasma processing apparatus 1. In the etching, the metal-containing resist film RM functions as a mask, and a recess is formed in the underlayer film UF based on the shape of the opening OP. When development is performed using the plasma processing apparatus 1 in step ST4, the etching may be performed consecutively in the same processing chamber 10 as step ST4, or may be performed in the processing chambers of different plasma processing apparatuses.

### <Configuration Example of Substrate Processing System>

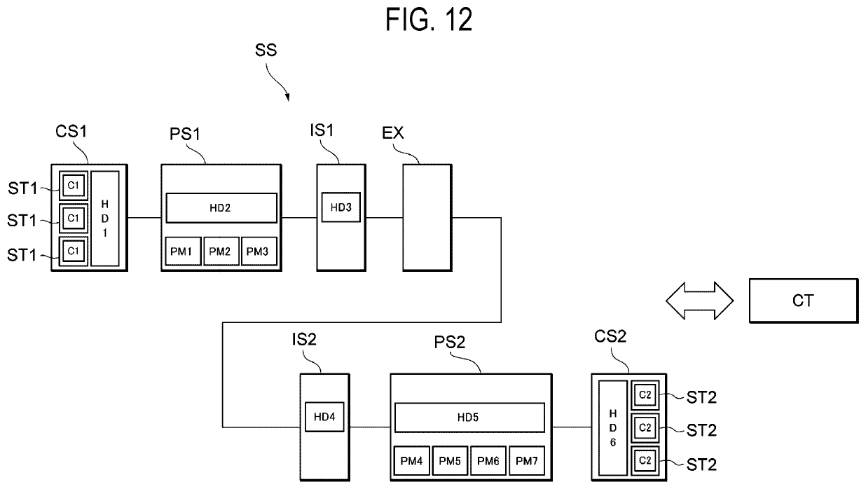

FIG. 12 is a block diagram for explaining a configuration example of a substrate processing system SS according to an exemplary embodiment. The substrate processing system SS includes a first carrier station CS1, a first processing station PS1, a first interface station IS1, an exposure apparatus EX, a second interface station IS2, a second processing station PS2, a second carrier station CS2, and a controller CT.

The first carrier station CS1 loads and unloads a first carrier C1 between the first carrier station CS1 and a system outside the substrate processing system SS. The first carrier station CS1 includes a mounting table including a plurality of first mounting plates ST1. The first carrier C1 is mounted on each of the first mounting plates ST1 in a state in which a plurality of substrates W are accommodated therein or in an empty state. The first carrier C1 has a housing capable of accommodating a plurality of substrates W therein. The first carrier C1 is, for example, a Front Opening Unified Pod (FOUP).

The first carrier station CS1 also transfers the substrate W between the first carrier C1 and the first processing station PS1. The first carrier station CS1 further includes a first transfer device HD1. The first transfer device HD1 is provided in the first carrier station CS1 so as to be located between the mounting table and the first processing station PS1. The first transfer device HD1 transfers and delivers the substrate W between the first carrier C1 on each of the first mounting plates ST1 and the second transfer device HD2 of the first processing station PS1. The substrate processing system SS may further include a load lock module. The load lock module may be provided between the first carrier station CS1 and the first processing station PS1. The load lock module can switch the pressure therein to an atmospheric pressure or a vacuum. The “atmospheric pressure” may be the pressure inside the first transfer device HD1. The “vacuum” refers to a pressure lower than the atmospheric pressure, and may be, for example, a medium vacuum of 0.1 Pa to 100 Pa. The pressure inside the second transfer device HD2 may be an atmospheric pressure or a vacuum. For example, the load lock module may transfer the substrate W from the first transfer device HD1, which is kept at an atmospheric pressure, to the second transfer device HD2, which is kept at a vacuum, and may also transfer the substrate W from the second transfer device HD2, which is kept at a vacuum, to the first transfer device HD1, which is kept at an atmospheric pressure.

The first processing station PS1 performs various processes on the substrate W. In one embodiment, the first processing station PS1 includes a pre-processing module PM1, a resist film forming module PM2, and a first heat treatment module PM3 (hereinafter collectively referred to as “first substrate processing module PMa”). The first processing station PS1 also includes a second transfer device HD2 that transfers the substrate W. The second transfer device HD2 transfers and delivers the substrate W between two designated first substrate processing modules PMa, and between the first processing station PS1 and the first carrier station CS1 or the first interface station IS1.

In the pre-processing module PM1, the substrate W is subjected to pre-processing. In one embodiment, the pre-processing module PM1 includes a temperature adjustment unit that adjusts the temperature of the substrate W, a high-precision temperature adjustment unit that adjusts the temperature of the substrate W with high precision, and an underlayer film formation unit that forms a part or all of an underlayer film on the substrate W. In one embodiment, the pre-processing module PM1 includes a surface modification processing unit that performs surface modification on the substrate W. Each processing unit of the pre-processing module PM1 may include a heat treatment apparatus 100 (see FIG. 1), a plasma processing apparatus 1 (see FIGS. 2 and 3), and/or a liquid processing apparatus 300 (see FIG. 4).

In the resist film forming module PM2, a resist film is formed on the substrate W. In one embodiment, the resist film forming module PM2 includes a dry coating unit. The dry coating unit forms a resist film on the substrate W using a dry process such as a vapor phase deposition method. In one example, the dry coating unit includes a CVD apparatus or an ALD apparatus that performs chemical vapor deposition of a resist film on the substrate W arranged in the chamber, or a PVD apparatus that performs physical vapor deposition of a resist film. The dry coating unit may be the heat treatment apparatus 100 (see FIG. 1) or the plasma processing apparatus 1 (see FIGS. 2 and 3).

In one embodiment, the resist film forming module PM2 includes a wet coating unit. The wet coating unit forms a resist film on the substrate W using a wet process such as a liquid deposition method. The wet coating unit may be, for example, the liquid processing apparatus 300 (see FIG. 4).

In one embodiment, an example of the resist film forming module PM2 includes both a wet coating unit and a dry coating unit.

In the first heat treatment module PM3, the substrate W is subjected to a heat treatment. In one embodiment, the first heat treatment module PM3 includes one or more of a pre-bake (Post Apply Bake: PAB) unit that performs a heat treatment on the substrate W on which a resist film is formed, a temperature adjustment unit that adjusts the temperature of the substrate W, and a high-precision temperature adjustment unit that adjusts the temperature of the substrate W with high precision. Each of these units may have one or more heat treatment apparatuses. In one example, the heat treatment apparatuses may be stacked one above another. The heat treatment apparatus may be, for example, the heat treatment apparatus 100 (see FIG. 1). Each heat treatment may be performed at a predetermined temperature using a predetermined gas.

The first interface station IS1 includes a third transfer device HD3. The third transfer device HD3 transfers and delivers the substrate W between the first processing station PS1 and the exposure apparatus EX. The third transfer device HD3 includes a housing that accommodates the substrate W, and may be configured to be able to control the temperature, humidity, pressure, and the like inside the housing.

The exposure apparatus EX uses an exposure mask (reticle) to expose the resist film on the substrate W. The exposure apparatus EX may be, for example, an EUV exposure apparatus including a light source that generates EUV light.

The second interface station IS2 includes a fourth transfer device HD4. The fourth transfer device HD4 transfers and delivers the substrate W between the exposure apparatus EX and the second processing station PS2. The fourth transfer device HD4 includes a housing that accommodates the substrate W, and may be configured to be able to control the temperature, humidity, pressure, and the like inside the housing.

The second processing station PS2 performs various processes on the substrate W. In one embodiment, the second processing station PS2 includes a second thermal treatment module PM4, a measurement module PM5, a developing module PM6, and a third heat treatment module PM7 (hereinafter collectively referred to as “second substrate processing module PMb”). The second processing station PS2 further includes a fifth transfer device HD5 that transfers the substrate W. The fifth transfer device HD5 transfers and delivers the substrate W between two designated second substrate processing modules PMb, and between the second processing station PS2 and the second carrier station CS2 or the second interface station IS2.

In the second heat treatment module PM4, the substrate W is heat-treated. In one embodiment, the heat treatment module PM4 includes one or more of a post-exposure bake (PEB) unit that heat-treats the substrate W after exposure, a temperature adjustment unit that adjusts the temperature of the substrate W, and a high-precision temperature adjustment unit that adjusts the temperature of the substrate W with high precision. Each of these units may include one or more heat treatment apparatuses. In one example, the heat treatment apparatuses may be stacked one above another. The heat treatment apparatus may be, for example, the heat treatment apparatus 100 (see FIG. 1). Each heat treatment may be performed at a predetermined temperature using a predetermined gas.

In the measurement module PM5, various measurements are performed on the substrate W. In one embodiment, the measurement module PM5 includes an imaging unit including a stage for placing the substrate W, an imaging device, an illumination device, and various sensors (temperature sensor, reflectance measurement sensor, etc.). The imaging device may be, for example, a CCD camera that captures an image of the appearance of the substrate W. Alternatively, the imaging device may be a hyperspectral camera that captures images by dispersing light into wavelengths. The hyperspectral camera may measure one or more of the pattern shape, dimension, film thickness, composition, and film density of the resist film.

In the developing module PM6, the substrate W is subjected to a developing process. In one embodiment, the developing module PM6 includes a dry developing unit that performs dry developing on the substrate W. The dry developing unit may be, for example, the heat treatment apparatus 100 (see FIG. 1) or the plasma processing apparatus 1 (see FIG. 2 and FIG. 3). In one embodiment, the developing module PM6 includes a wet developing unit that performs wet developing on the substrate W. The wet developing unit may be, for example, the liquid processing apparatus 300 (FIG. 4). In one embodiment, the developing module PM6 includes both a dry developing unit and a wet developing unit.

In the third heat treatment module PM7, the substrate W is subjected to a heat treatment. In one embodiment, the third heat treatment module PM7 includes one or more of a post bake (PB) unit that heat-treats the substrate W after development, a temperature adjustment unit that adjusts the temperature of the substrate W, and a high-precision temperature adjustment unit that adjusts the temperature of the substrate W with high precision. Each of these units may include one or more heat treatment apparatuses. In one example, the heat treatment apparatuses may be stacked one above another. The heat treatment apparatus may be, for example, the heat treatment apparatus 100 (see FIG. 1). Each heat treatment may be performed at a predetermined temperature using a predetermined gas.

The second carrier station CS2 loads and unloads the second carrier C2 between the second carrier station CS2 and a system outside the substrate processing system SS. The configuration and function of the second carrier station CS2 may be similar to those of the first carrier station CS1 described above.

The controller CT controls each component of the substrate processing system SS to perform a given process on the substrate W. The controller CT stores a recipe in which a process procedure, process conditions, transfer conditions, and the like are set, and controls each component of the substrate processing system SS to perform a given process on the substrate W in accordance with the recipe. The controller CT may have some or all of the functions of each of the controllers (the controller 200, the controller 2, and the controller 400 shown in FIGS. 1 to 4).

### <One Example of Substrate Processing Method>

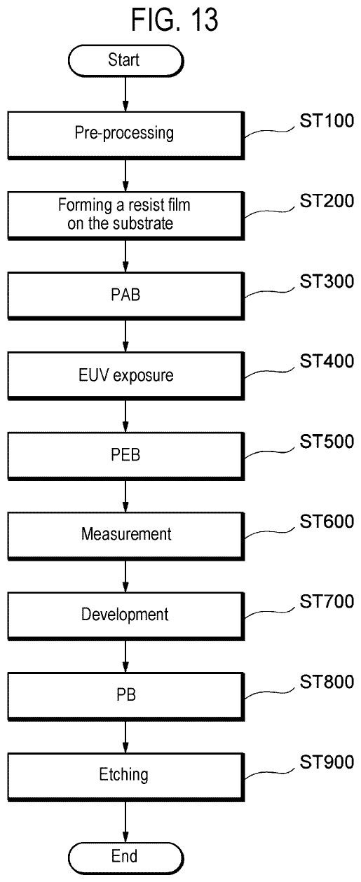

FIG. 13 is a flowchart showing a substrate processing method (hereinafter also referred to as “method MT”) according to an exemplary embodiment. As shown in FIG. 13, the method MT includes step ST100 of pre-processing a substrate, step ST200 of forming a resist film on the substrate, step ST300 of performing a heat treatment (pre-bake: PAB) on the substrate on which the resist film is formed, step ST400 of exposing the substrate to EUV light, step ST500 of performing a heat treatment (post-exposure bake: PEB) on the substrate after exposure, step ST600 of measuring the substrate, step ST700 of developing the resist film on the substrate, step ST800 of performing a heat treatment (post-bake: PB) on the substrate after development, and step ST900 of etching the substrate. The method MT does not need to include one or more of the above steps. For example, the method MT may not include step ST600, and step ST700 may be performed after step ST500.

The method MT may be performed by using a substrate processing system SS shown in FIG. 12. In the following, a case where the controller CT of the substrate processing system SS controls each part of the substrate processing system SS to perform the method MT on the substrate W will be described as an example.

### (Step ST100: Pre-processing)

First, the first carrier C1 containing multiple substrates W is loaded into the first carrier station CS1 of the substrate processing system SS. The first carrier C1 is mounted on the first mounting plate ST1. Next, the first transfer device HD1 sequentially takes out each substrate W from the first carrier C1 and transfers the substrate W to the second transfer device HD2 of the first processing station PS1. The substrate W is transferred to the pre-processing module PM1 by the second transfer device HD2. The pre-processing module PM1 performs pre-processing on the substrate W. The pre-processing may include, for example, one or more of the temperature adjustment for the substrate W, the formation of a part or all of the underlayer film on the substrate W, the heat treatment of the substrate W, and the high-precision temperature adjustment of the substrate W. The pre-processing may include surface modification processing for the substrate W.

### (Step ST200: Resist Film Formation)

Next, the substrate W is transferred to the resist film forming module PM2 by the second transfer device HD2. A resist film is formed on the substrate W by the resist film forming module PM2. In one embodiment, the resist film is formed by a wet process such as a liquid phase deposition method. For example, the resist film is formed by spin-coating a resist film on the substrate W using the wet coating unit of the resist film forming module PM2. In one embodiment, the resist film is formed on the substrate W by a dry process such as a vapor phase deposition method. For example, the resist film is formed by vapor-depositing a resist film on the substrate W using the dry coating unit of the resist film forming module PM2. The formation of the resist film in step ST200 may be performed using the present processing method (see FIG. 5). That is, the metal-containing resist film RM having a first resist film RM1 and a second resist film RM2 may be formed on the substrate W.

The resist film may be formed on the substrate W using both a dry process and a wet process. For example, after a first resist film is formed on the substrate W by a dry process, a second resist film may be formed on the first resist film by a wet process. In this case, the film thicknesses and the materials and/or compositions of the first resist film and the second resist film may be the same or different.

### (Step ST300: PAB)

Next, the substrate W is transferred to the first heat treatment module PM3 by the second transfer device HD2. The substrate W is subjected to a heat treatment (pre-bake: PAB) by the first heat treatment module PM3. The pre-bake may be performed in an air atmosphere or an inert atmosphere. The pre-bake may be performed by heating the substrate W to 50 degrees C. or more, or 80 degrees C. or more. The heating temperature of the substrate W may be 250 degrees C. or less, 200 degrees C. or less, or 150 degrees C. or less. In one example, the heating temperature of the substrate may be 50 degrees C. or more and 250 degrees C. or less. When the resist film is formed by the dry process in step ST200, in one embodiment, the pre-bake may be performed continuously in the dry coating unit that has performed step ST200. In one embodiment, after the pre-bake, a process (Edge Bead Removal: EBR) for removing the resist film at the edge of the substrate W may be performed.

### (Step ST400: EUV Exposure)

Next, the substrate W is transferred by the second transfer device HD2 to the third transfer device HD3 of the first interface station IS1. The substrate W is then transferred by the third transfer device HD3 to the exposure apparatus EX. The substrate W is exposed to EUV light through an exposure mask (reticle) in the exposure apparatus EX. EUV has a wavelength in the range of, for example, 10 to 20 nm. EUV may have a wavelength in the range of 11 to 14 nm, and in one example, has a wavelength of 13.5 nm. As a result, a first region that has been exposed to EUV light and a second region that has not been exposed to EUV light are formed on the substrate W in conformity with the pattern of the exposure mask (reticle). In one embodiment, the film thickness of the first region may be smaller than the film thickness of the second region 2.

### (Step ST500: PEB)

Next, the substrate W is transferred from the fourth transfer device HD4 of the second interface station IS2 to the fifth transfer device HD5 of the second processing station PS2. The substrate W is then transferred by the fifth transfer device HD5 to the second heat treatment module PM4. The substrate W is then subjected to a heat treatment (post-exposure bake: PEB) in the second heat treatment module PM4. The post-exposure bake may be performed in an air atmosphere. The post-exposure bake may also be performed by heating the substrate W to 180 degrees C. or higher and 250 degrees C. or lower.

### (Step ST600: Measurement)

Next, the substrate W is transferred to the measurement module PM5 by the fifth transfer device HD5. The measurement module PM5 measures the substrate W. The measurement may be an optical measurement or another measurement. In one embodiment, the measurement by the measurement module PM5 includes measuring the appearance and/or dimensions of the substrate W using a CCD camera. In one embodiment, the measurement by the measurement module PM5 includes measuring one or more of the pattern shape, dimension, film thickness, composition, and film density of the resist film (hereinafter also referred to as “pattern shape, and the like”) using a hyperspectral camera.

In one embodiment, the controller CT determines whether or not there is an exposure abnormality in the substrate W based on the measured appearance, dimension, and/or pattern shape of the substrate W. In one embodiment, if the controller CT determines that there is an exposure abnormality, the substrate W may be reworked or discarded without being developed in step ST700. The rework of the substrate W may be performed by removing the resist on the substrate W and returning to step ST200 to form a resist film again. Rework after development may cause damage to the substrate W. However, by performing the rework before development, damage to the substrate W can be avoided or suppressed.

### (Step ST700: Development)

Next, the substrate W is transferred to the developing module PM6 by the fifth transfer device HD5. In the developing module PM6, the resist film of the substrate W is developed. Either the first region exposed to EUV or the second region not exposed to EUV is selectively removed by development. The developing process may be performed by dry development or wet development. The developing process may be performed by combining dry development and wet development. After or during the developing process, a desorption process may be performed one or more times. The desorption process includes removing scum from the surface of the resist film and the surface of the underlayer film UF or smoothing the surfaces by using an inert gas such as helium or the like, or the plasma of the inert gas.

### (Step ST800: PB)

Next, the substrate W is transferred by the fifth transfer device HD5 to the third heat treatment module PM7, and is subjected to a heat treatment (post-bake). The post-bake may be performed in an air atmosphere, or in a reduced pressure atmosphere containing N₂ or O₂. The post-bake may be performed by heating the substrate W to 150 degrees C. or higher and 250 degrees C. or lower. The post-bake may be performed in the second heat treatment module PM4 instead of the third heat treatment module PM7. In one embodiment, after the post-bake, the substrate W may be optically measured by the measurement module PM5. Such a measurement may be performed in addition to or instead of the measurement in step ST600. In one embodiment, the controller CT determines the presence or absence of abnormalities such as defects, scratches, and foreign matter adhesion in the developed pattern of the substrate W based on the measured appearance and dimensions of the substrate W and/or the pattern shape. In one embodiment, when the controller CT determines that there is an abnormality, the substrate W may be reworked or discarded without performing etching in step ST900. In one embodiment, when the controller CT determines that there is an abnormality, the opening dimension of the resist film of the substrate W may be adjusted using a dry coating unit (such as a CVD apparatus or an ALD apparatus).

### (Step ST900: Etching)

After step ST800 is performed, the substrate W is transferred by the fifth transfer device HD5 to the sixth transfer device HD6 of the second carrier station CS2, and is transferred by the sixth transfer device HD6 to the second carrier C2 of the second mounting plate ST2. The second carrier C2 is then transferred to a plasma processing system (not shown). The plasma processing system may be, for example, the plasma processing system shown in FIGS. 2 and 3. In the plasma processing system, the underlayer film UF of the substrate W is etched using the developed resist film as a mask. Thus, the method MT is ended. In step ST700, when the resist film is developed using the plasma processing apparatus, the etching may be performed subsequently in the plasma processing chamber of the plasma processing apparatus. In addition, when the second processing station PS2 includes a plasma processing module in addition to the developing module PM6, the etching may be performed in the plasma processing module. The above-mentioned desorption process may be performed one or more times before or during the etching.

The embodiments of the present disclosure further include the following aspects.

### Supplementary Note 1

A substrate processing method, comprising:
   (a) providing a substrate having an underlayer film; and
   (b) forming a metal-containing resist film on the underlayer film, wherein (b) includes (b1) forming a first resist film containing a metal on the underlayer film, and (b2) forming a second resist film containing the metal in a composition ratio different from the composition ratio of the metal in the first resist film on the first resist film.

### Supplementary Note 2

The method of Supplementary Note 1, wherein the composition ratio of the metal in the second resist film is lower than the composition ratio of the metal in the first resist film.

### Supplementary Note 3

The method of Supplementary Note 1 or 2, wherein the metal-containing resist film contains at least one metal selected from a group consisting of Sn, Hf, and Ti.

### Supplementary Note 4

The method of any one of Supplementary Notes 1 to 3, wherein in (b), the metal-containing film is formed such that the composition ratio of the metal is changed stepwise or continuously upward from the underlayer film.

### Supplementary Note 5

The method of any one of Supplementary Notes 1 to 4, wherein each of (b1) and (b2) includes applying a solution onto the substrate, and the composition ratio of the metal in the solution used in (b2) is lower than the composition ratio of the metal in the solution used in (b1).

### Supplementary Note 6

The method of Supplementary Note 5, wherein (b1) includes heating the substrate on which the solution is applied.

### Supplementary Note 7

The method of Supplementary Note 5 or 6, wherein (b2) includes heating the substrate on which the solution is applied.

### Supplementary Note 8

The method of any one of Supplementary Notes 1 to 4, wherein each of (b1) and (b2) includes providing a mixed gas containing a metal-containing gas and an oxidizing gas to the substrate, and the flow rate ratio of the metal-containing gas to the total flow rate of the mixed gas or the total flow rate of the mixed gas is lower in (b2) than in (b1).

### Supplementary Note 9

The method of any one of Supplementary Notes 1 to 4, wherein each of (b1) and (b2) includes alternately supplying a first gas including a metal-containing gas and a second gas including an oxidizing gas, and the flow rate ratio of the first gas to the second gas or the total flow rate of the first gas and the second gas is lower in (b2) than in (b1).

### Supplementary Note 10

The method of Supplementary Note 8 or 9, wherein the metal-containing gas includes a metal-containing organic precursor.

### Supplementary Note 11

The method of any one of Supplementary Notes 8 to 10, wherein the oxidizing gas includes at least one selected from a group consisting of a H₂O gas, a H₂O₂ gas, an O₃ gas, and an O₂ gas.

### Supplementary Note 12

The method of any one of Supplementary Notes 8 to 11, wherein in (a), the substrate is provided on a substrate support, and the temperature of the substrate support in (b2) is lower than the temperature of the substrate support in (b1).

### Supplementary Note 13

The method of any one of Supplementary Notes 8 to 12, wherein (b1) includes heating the substrate.

### Supplementary Note 14

The method of any one of Supplementary Notes 8 to 13, wherein (b2) includes heating the substrate.

### Supplementary Note 15

The method of any one of Supplementary Notes 1 to 14, wherein (b) includes (b3) forming, on the second resist film, one or more layers of a resist film containing the metal in a composition ratio different from the composition ratios of the metal in the first resist film and the second resist film.

### Supplementary Note 16

The method of any one of Supplementary Notes 1 to 15, further comprising:
   (c) after (b), heating the substrate.

### Supplementary Note 17

The method of any one of Supplementary Notes 1 to 16, further comprising:
   (d) after step (b), exposing the substrate to form an exposed first region and an unexposed second region in the metal-containing resist film.

### Supplementary Note 18

The method of Supplementary Note 17, further comprising:
   (e) after step (d), developing the substrate to selectively remove the second region from the metal-containing resist film.

### Supplementary Note 19

A substrate processing method, comprising:
   (a) providing a substrate having an underlayer film and a metal-containing resist film formed on the underlayer film, the metal-containing resist film including a first resist film formed on the underlayer film and containing a metal, and a second resist film formed on the first resist film and containing the metal in a composition ratio different from the composition ratio of the metal in the first resist film, the metal-containing resist film including an exposed first region and an unexposed second region; and
   (b) developing the substrate to selectively remove the second region from the metal-containing resist film.

### Supplementary Note 20

The method of Supplementary Note 18 or 19, further comprising:
   (f) etching the underlayer film after developing the substrate to selectively remove the second region from the metal-containing resist film.

### Supplementary Note 21

A substrate processing system, comprising:
   one or more substrate processing apparatuses; and
   a controller,
   wherein the controller is configured to cause the one or more substrate processing apparatuses to execute controls including (a) a control of providing a substrate having an underlayer film, and (b) a control of forming a metal-containing resist film on the underlayer film, and
   (b) includes (b1) a control of forming a first resist film containing a metal on the underlayer film, and (b2) a control of forming a second resist film containing the metal in a composition ratio different from the composition ratio of the metal in the first resist film on the first resist film.

### Supplementary Note 22

A substrate processing system, comprising:
   one or more substrate processing apparatuses; and
   a controller,
   wherein the controller is configured to cause the one or more substrate processing apparatuses to execute (a) a control of providing a substrate having an underlayer film and a metal-containing resist film formed on the underlayer film, the metal-containing resist film including a first resist film formed on the underlayer film and containing a metal, and a second resist film formed on the first resist film and containing the metal in a composition ratio different from the composition ratio of the metal in the first resist film, the metal-containing resist film including an exposed first region and an unexposed second region, and (b) a control of developing the substrate to selectively remove the second region from the metal-containing resist film.

### Supplementary Note 23

A device manufacturing method, comprising:
   (a) providing a substrate having an underlayer film; and
   (b) forming a metal-containing resist film on the underlayer film,
   wherein (b) includes (b1) forming a first resist film containing a metal on the underlayer film, and (b2) forming a second resist film containing the metal in a composition ratio different from the composition ratio of the metal in the first resist film on the first resist film.

### Supplementary Note 24

A program that causes a computer of a substrate processing system including one or more substrate processing apparatuses and a controller to execute:
   (a) a control of providing a substrate having an underlayer film; and
   (b) a control of forming a metal-containing resist film on the underlayer film,
   wherein (b) includes (b1) a control of forming a first resist film containing a metal on the underlayer film, and (b2) a control of forming a second resist film containing the metal in a composition ratio different from the composition ratio of the metal in the first resist film on the first resist film.

### Supplementary Note 25

A recording medium that stores the program of Supplementary Note 24.

According to the present disclosure in some embodiments, it is possible to provide a technique for adjusting the exposure sensitivity of a resist film.

While certain embodiments have been described, these embodiments have been presented by way of example only, and are not intended to limit the scope of the disclosures. Indeed, the embodiments described herein may be embodied in a variety of other forms. Furthermore, various omissions, substitutions, and changes in the form of the embodiments described herein may be made without departing from the spirit of the disclosures. The accompanying claims and their equivalents are intended to cover such forms or modifications as would fall within the scope and spirit of the disclosures.

What is claimed is:

1. A substrate processing method, comprising:
(a) providing a substrate having an underlayer film; and
(b) forming a metal-containing resist film on the underlayer film,
wherein (b) includes (b1) forming a first resist film containing a metal on the underlayer film, and (b2) forming a second resist film containing the metal in a composition ratio different from the composition ratio of the metal in the first resist film on the first resist film.

2. The method of claim 1, wherein the composition ratio of the metal in the second resist film is lower than the composition ratio of the metal in the first resist film.

3. The method of claim 1, wherein the metal-containing resist film contains at least one metal selected from a group consisting of Sn, Hf, and Ti.

4. The method of claim 1, wherein in (b), the metal-containing resist film is formed such that the composition ratio of the metal is changed stepwise or continuously upward from the underlayer film.

5. The method of claim 1, wherein each of (b1) and (b2) includes applying a solution onto the substrate, and the composition ratio of the metal in the solution used in (b2) is lower than the composition ratio of the metal in the solution used in (b1).

6. The method of claim 5, wherein (b1) includes heating the substrate on which the solution is applied.

7. The method of claim 5, wherein (b2) includes heating the substrate on which the solution is applied.

8. The method of claim 1, wherein each of (b1) and (b2) includes providing a mixed gas containing a metal-containing gas and an oxidizing gas to the substrate, and a flow rate ratio of the metal-containing gas to a total flow rate of the mixed gas or the total flow rate of the mixed gas is lower in (b2) than in (b1).

9. The method of claim 1, wherein each of (b1) and (b2) includes alternately supplying a first gas including a metal-containing gas and a second gas including an oxidizing gas, and a flow rate ratio of the first gas to the second gas or a total flow rate of the first gas and the second gas is lower in (b2) than in (b1).

10. The method of claim 8, wherein the metal-containing gas includes a metal-containing organic precursor.

11. The method of claim 8, wherein the oxidizing gas includes at least one selected from a group consisting of a H₂O gas, a H₂O₂ gas, an O₃ gas, and an O₂ gas.

12. The method of claim 8, wherein in (a), the substrate is provided on a substrate support, and a temperature of the substrate support in (b2) is lower than a temperature of the substrate support in (b1).

13. The method of claim 8, wherein (b1) includes heating the substrate.

14. The method of claim 8, wherein (b2) includes heating the substrate.

15. The method of claim 1, wherein (b) includes (b3) forming, on the second resist film, one or more layers of a resist film containing the metal in a composition ratio different from the composition ratios of the metal in the first resist film and the second resist film.

16. The method of claim 1, further comprising:
(c) after (b), heating the substrate.

17. The method of claim 1, further comprising:
(d) after step (b), exposing the substrate to form an exposed first region and an unexposed second region in the metal-containing resist film.

18. The method of claim 17, further comprising:
(e) after step (d), developing the substrate to selectively remove the second region from the metal-containing resist film.

19. A substrate processing method, comprising:
(a) providing a substrate having an underlayer film and a metal-containing resist film formed on the underlayer film, the metal-containing resist film including a first resist film formed on the underlayer film and containing a metal, and a second resist film formed on the first resist film and containing the metal in a composition ratio different from the composition ratio of the metal in the first resist film, the metal-containing resist film including an exposed first region and an unexposed second region; and
(b) developing the substrate to selectively remove the second region from the metal-containing resist film.

20. The method of claim 18, further comprising:
(f) etching the underlayer film after developing the substrate to selectively remove the second region from the metal-containing resist film.

21. A substrate processing system, comprising:
one or more substrate processing apparatuses; and
a controller,
wherein the controller is configured to cause the one or more substrate processing apparatuses to execute controls including (a) a control of providing a substrate having an underlayer film, and (b) a control of forming a metal-containing resist film on the underlayer film, and
(b) includes (b1) a control of forming a first resist film containing a metal on the underlayer film, and (b2) a control of forming a second resist film containing the metal in a composition ratio different from the composition ratio of the metal in the first resist film on the first resist film.

22. A substrate processing system, comprising:
one or more substrate processing apparatuses; and
a controller,
wherein the controller is configured to cause the one or more substrate processing apparatuses to execute (a) a control of providing a substrate having an underlayer film and a metal-containing resist film formed on the underlayer film, the metal-containing resist film including a first resist film formed on the underlayer film and containing a metal, and a second resist film formed on the first resist film and containing the metal in a composition ratio different from the composition ratio of the metal in the first resist film, the metal-containing resist film including an exposed first region and an unexposed second region, and (b) a control of developing the substrate to selectively remove the second region from the metal-containing resist film.
